(19) United States
(12) Patent Application Publication
(10) Pub. No.: US 2004/0017232 A1
(43) Pub. Date: Jan. 29, 2004

(54) Frequency dividing circuit arrangement

(76) Inventor: Juergen Adams, Villingen-Schwenningen (DE)

Correspondence Address: SIEMENS SCHWEIZ, I-44, INTELLECTUAL PROPERTY, ALBISRIEDERSTRASSE 245, ZURICH, CH-8047, CH

(21) Appl. No.: 10/445,066

(22) Filed: May 27, 2003

(30) Foreign Application Priority Data
May 24, 2002 (DE) 102 23 169.9

(51) Int. Cl. H03B 19/00

(52) U.S. Cl. 327/114

(57) ABSTRACT

A frequency dividing circuit arrangement is disclosed which comprises a multivibrator or with feedback for dividing frequencies. A current registering means is connected to the output of the multivibrator. The curt registering means registers the output current of the multivibrator and causes the multivibrator to be reset when all overload or fault occurs. As soon as the fault state is eliminated, it is possible to resume normal operation without a cooling down phase. Thermal overloading of an output stage can thus be advantageously avoided. The frequency divider circuit is preferably provided for application in motor vehicles.

### CROSS REFERENCE TO RELATED APPLICATIONS

The present application claims priority to German patent application number 10223169.9, filed May 24, 2002 which is herein incorporated by reference.

### BACKGROUND OF THE INVENTION

The present invention relates generally to the field of microelectronics and more particularly to a frequency dividing circuit arrangement. The present arrangement will be discussed with non-limiting application to automobile electronics.

Pulse dividers are normally used, on the one hand, to isolate a high frequency input signal from an output signal and, on the other hand, to make available an output signal with a relatively low frequency with which terminals can be actuated in accordance with their specifications. Such frequency dividers or pulse dividers are used, for example in motor vehicles in order to convert signals made available by a pulse source into signals with a relatively low frequency, amplify them and, after conditioning them in this way, make them available to other dices. Other devices possible here are, for example, radios, navigation aids, cruise controllers, brake boosters and traction control systems. The pulses which are made available by the pulse source are generally travel pulses with which it is possible to determine a curt travel speed with respect to the underlying surface.

In particular when such pulse divider circuits or frequency divider circuits are used in motor vehicles it may be desired, when a fault state is present to suppress the output signal of the frequency divider, or to protect the frequency divider and/or downstream devices against the high currents which occur. Such a fault state may be, for example, a short circuit of the output of the frequency divider to the supply voltage. The supply voltage here is the voltage of the motor vehicle's on-board electrical system of 12 or 24 volts.

In order to make available a protection against short circuits to the supply voltage, a protective resistor, which is capable of intercepting the high short circuit currents which are associated with the short circuit, could be connected to the output of the frequency divider. Alternatively, temperature-dependent protective resistors, referred to as PTC (Positive Temperature Coefficient) resistors could also be used so that in the case of a short circuit the power loss which is increased can be limited to all favorable values. Finally, by using thermally protected switching transistors such as are available, for example, under the tradename TEMPFET, it would be possible to provide protection against high short circuit currents. However, this solution would require a large amount of space and be costly.

Furthermore, it is desirable for the signal output of the frequency divider to be embodied as an open collector output in order to be able to actuate electrical pull-up loads.

Finally, during normal operation, when the output of the frequency divider is active and a logic low level is present at the output of the frequency divider, the residual voltage which remains at the output should be lower than 0.8 volts.

### SUMMARY OF THE INVENTION

An advantage of the present invention is achieved by means of a frequency dividing circuit arrangement, comprising

a multivibrator configured as a frequency divider with a clock input for feeding in an input signal, with an output at which a signal with a divided frequency of the input signal is made available, and with a resetting input,

a current registering means, comprising a comparator with a fist input which is coupled to the output of the multivibrator in order to register an output curt which is dependent on the signal with the divided frequency, with a second input which is coupled to a reference source, and with an output which is coupled to the resetting input of the multivibrator and actuates the resetting input as a function of a comparison result in the comparator.

The multivibrator is actuated at its clock input by means of an input signal and makes available at its output a signal with the divided frequency of the input signal preferably with half the input signal frequency. The current resist means which is connected to the output of the multivibrator registers the output current which is dependent on the output signal with the divided signal frequency, and compares this current value or a signal which is dependent on this current value with a reference signal which is made available by the reference source. If the output current exceeds a definable threshold value which is set by the reference source, the multivibrator is reset by appropriately actuating its reset input.

Accordingly, it is possible to distinguish between normal operation and faulty operation. During normal operation, the multivibrator operates as a frequency divider. For this purpose, an inverting output of the multivibrator can preferably be connected to a data input thereof in a feedback arrangement.

During faulty operation, for example when a short circuit is present between the output and the supply potential, an unacceptably high output current, dependent on the signal with the divided frequency, typically flows. This output current accordingly flows as a function of the logic state which is present at the output of the multivibrator at that particular time. The unacceptably high output current is detected using the current registering means by comparison with a value of a manipulated variable, and when a fault is present the multivibrator is reset, This procedure is repeated for as long as there is a short circuit. As soon as the short circuit is eliminated, the circuit becomes operational again directly and advantageously without a recovery time.

As frequency dividing circuit arrangements in any case usually comprise a multivibrator which is configured as a frequency dividers the present principle may be implemented with little expenditure by using these circuits as a basis. An additional advantage is obtained by the possibility of returning into a normal operating mode without a recovery time, as is known from the thermal protection devices mentioned at the beginning.

According to one embodiment of the invention, an output transistor is provided with a control input which is coupled to the out of the multivibrator and with a controlled path having a terminal which is connected to the first input of the comparator for feeding in the output current. The other terminal of the controlled path, which preferably forms the output of the frequency divider, is preferably embodied as an open collector output or open drain output. As a result, electrical loads which are defined by a pull-up resistor connected to the supply potential can be advantageously integrated,

In order to register the output current which depends on the signal with the divided frequency, a negative feedback resistor is preferably provided. The latter is connected between the terminal of the controlled path of the output transistor and a reference potential terminal and makes available a voltage which is assigned to the output current. Said voltage can be tapped at the connecting node between the controlled path of the output transistor and the negative feedback resistor and fed to the comparator at its fist input terminal. This negative feedback of the current advantageously brings about cut limitation at the output transistor so that overloading of the output transistor is avoided up to the time when the output transistor is switched off by means of the resetting of the multivibrator. Owing to the very short time period for which current flows, thermal overloading of the output transistor is avoided in a particularly effective way.

According to another embodiment of the present invention, a damping capacitor is provided which is connected in parallel with the negative feedback resistor and prevents voltage peaks at the negative feedback resistor, said voltage peaks being caused, for example, by line capacitors or optional suppression capacitors du normal switch-over operations. Such voltage peaks could lead to undesired resetting of the multivibrator without a fault state actually being present and the damping capacitor makes it possible to reliably distinguish said peak currents from actual fault states.

In order to avoid undesired, line-bound or irradiated radio-frequency interference components, a suppression capacitor may be connected between the second terminal of the controlled path of the output transistor and a reference potential terminal.

### BRIEF DESCRIPTION OF THE SEVERAL VIEWS OF THE DRAWINGS

The novel features believed characteristic of the invention are set out in the claims below, the invention itself however, as well as other features and advantages thereof, are best understood by reference to the detailed description, which follows, when read in conjunction with the accompanying drawing, wherein:

FIG. 1 depicts a first exemplary embodiment of the present frequency divider circuit by means of a circuit diagram;

FIG. 2 depicts an exemplary embodiment of an electrical load which can be connected to the frequency divider in FIG. 1;

FIG. 3 depicts a second exemplary embodiment of a frequency divider circuit according to the invention by means of a circuit diagram;

FIG. 4 depicts a third exemplary embodiment of a frequency divider circuit according to the present principle by means of a circuit diagram; and

FIG. 5 depicts an application example of the frequency divider circuits in FIGS. 1, 2 and 4 in a motor vehicle by means of a simplified block circuit diagram.

DETAILED DESCRIPTION Of THE INVENTION

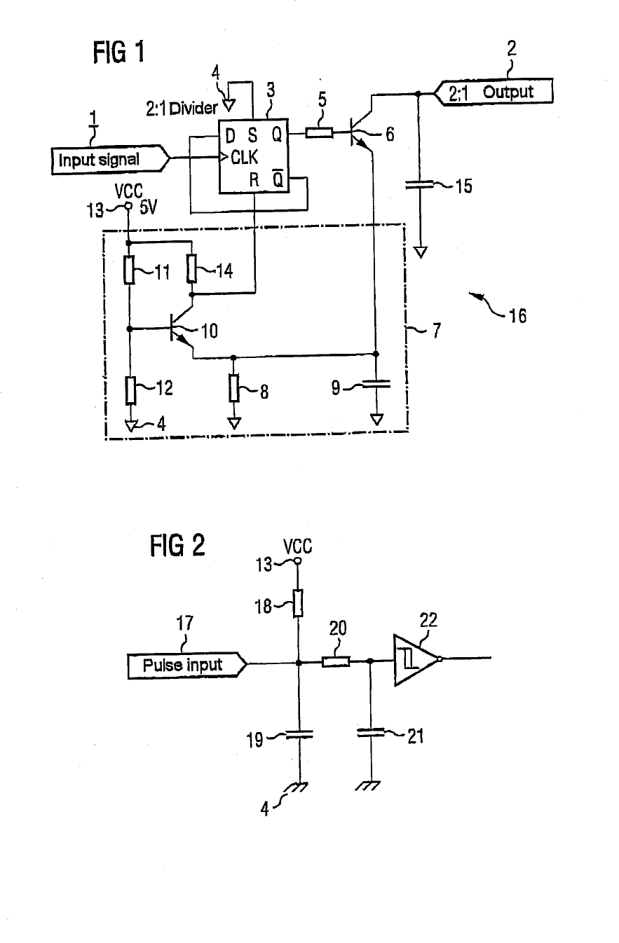

FIG. 1 depicts a frequency dividing circuit 16. An input signal with a frequency which is to be divided may be fed to an input 1 of the frequency divider circuit, and a signal with a divided frequency of the input signal is made available at the output 2 of the frequency divider circuit. The frequency dividing circuit arrangement comprises a multivibrator 3 which is configured as a frequency divider and embodied as a flipflop. The latter comprises a data input D, a clock input CLK, an output Q, an inverting output Q′, a setting input S, and a resetting input R. The setting input S is connected to a reference potential terminal 4. The clock input CLK of the flipflop 3 is connected to the input 1 of the frequency divider, So that the flipflop 3 operates as a 2:1 frequency divider, a feedback is provided by connecting the inverting output Q′ to the data input D. The output Q of the flipflop 3 is connected via a base resistor 5 to an npn-type output transistor 6 at its base terminal, said transistor being constructed using bipolar technology. The collector terminal of the output transistor 6 is connected to the output 2 of the frequency divider circuit. This output is configured as an open collector output The emitter terminal is connected to a current register means 7 which registers the output current at the output 2 and through the transistor 6 and actuates the flipflop 3 as a function of this output current For this purpose, the current registering means 7 is connected to the resetting input R of the flipflop 3.

The current registering means 7 comprises a negative feedback resistor 8 which connects the emitter terminal of the output transistor 6 to reference potential terminal, 4. A damping capacitor 9 is connected in parallel with the negative feedback resistor 8. A further transistor 10, which operates as a comparator, is connected by its emitter terminal to the emitter terminal of the output transistor 6. The emitter terminal of the transistor 10 thus forms a first input of a comparator. The base terminal of the transistor 10, which is connected via a voltage divider 11, 12 to a supply potential terminal 13, forms the second input terminal. The voltage divider comprises two resistors 11, 12 which are connected between the supply potential terminal 13 and the reference potential terminal 4. In addition, in order to form the comparator, a resistor 14 is provided which connects the supply potential terminal 13 to the collector terminal of the transistor 10. The collector terminal of the transistor 10, which constitutes the output of the comparator, is connected to the resetting input of the flipflop 3. In addition, a suppression capacitor 15 for filtering out radio frequency interference components is connected between the output 2 of the frequency divider and the reference potential terminal 4.

The D-flipflop 3 has the property that the output Q can be placed in the low state by applying a high signal to the resetting input R.

In order to explain the method of operation of the circuit, two operating modes will be considered separately below, specifically a normal operating mode and a short cat operating mode. In the normal operating mode, an input signal is supplied to the clock input CLK of the flipflop 3, said input signal switching the output Q backward and forward at each clock between a logic low and a logic high state so that a 2:1 frequency division takes place. The output transistor 6 is switched on and off as a function of the logic state at the output Q. In the switched-on state, a current from the output 2 flows to ground, for example through a pull-up resistor 18 (explained later with reference to FIG. 2) in an electrical load, through the output transistor 6 and the negative feedback resistor 8. A low voltage drops across the resistor 8, however this voltage is not sufficient to change the conductive state of the transistor 10.

In the short circuit operating mode it is assumed that the collector terminal of the output transistor 6 is connected to the operating voltage VCC of the frequency divider circuit If the output Q of the flipflop 3 changes into a high state as a function of a sensor clock at the clock input CLK, the transistor 6 is switched on. As supply potential is applied owing to the fault state at the output 2, a large current flows through the output transistor 6 and through the negative feedback resistor 8. This relatively large flow of ca uses a negative current to become established at the emitter terminal of the output transistor 6 owing to the voltage drop across the resistor 8. Consequently, as the signal present at the base terminal of the output transistor 6 is relatively small in comparison with its emitter terminal, the conductivity of the output transistor 6 drops. As the voltage drops across the negative feedback resistor 8, the emitter terminal of the transistor 10 is at about the same time raised in its potential in such a way that the base-emitter voltage approaches zero volts or becomes negative. As a result, the transistor 10 switches off. This in turn brings about a high signal at the resetting input R of the flipflop 3 via the resistor 14. The resetting signal immediately resets the output Q of the flipflop 3. As a result, the transistor 6 changes into its switched off state. The output signal at the output 2 due to the fault can accordingly only make available a flow of curt for such a short time that no thermal damage can occur as a result of the short circuit. At the next clock cycle at the input 1 of the frequency divider circuit or at the next occurrence of a high level in the input signal CLK, the described process repeats for as long as the short circuit to the supply potential occurs. As soon as the short circuit disappears, the frequency divider circuit is operational again, immediately, and advantageously without a recovery time. In contrast to thermal protection mechanisms, no cooling-phase is needed.

For a rated load current at the output 2 of approximately 20 mA, a resistance value of 22 ohms is therefore suitable here for the negative feedback resistor 8. Generally, the negative feedback resistor should be configured in such a way that a negative feedback of the current, which brings about a rise in the potential at the emitter of the transistor 6, causes the current in this transistor 6 to be limited so that a current overload does not occur in the short time period up to the switching off of the transistor as a result of the resetting of the flipflop 3.

As a function of the reference voltage which is made available by the voltage divider 11, 12 for the comparator 10, 14, the threshold for the changing over of the reset signal from the low state into the high state, said signal being fed to the flipflop 3 at its resetting input R, may be approximately determined in accordance with the rule

$${I}_{threshold} = ( {V}_{cc} \cdot \frac{{R}_{12}}{{R}_{11} + {R}_{12}} - {U}_{RE10} ) : {R}_{8}$$

Here, the current I_{threshold} constitutes the output current so that a short circuit is not in fact detected. The supply voltage V_{cc} is typically in the range of 5 volts, while the base-emitter voltage U_{ABR10} of the transistor 10 is approximately 0.6 volt. R₈, R₁₁, R₁₂ represent the resistor values of the respective resistors 8, 11, 12.

When a bipolar npn-transistor 10 is used, the resistance divider 11, 12 is used to set that voltage which, minus the base-emitter voltage of the transistor 10, has to drop across the negative feedback resistor 8 in order to switch off the transistor and thus generate the reset signal. For a limiting current I_{threshold}±25 mA, it is possible, for example, to specify the following resistance values:

R₁₁+10 kohm,

R₁₂+3.3 kohm,

R₈=22 ohm,

V_{CC}=5 volt.

The present circuit thus connects a 2:1 frequency division with a protective circuit for protecting against short circuits to the supply voltage and in doing so avoids the disadvantages of a thermal protection device. The principle described can be implemented with little expenditure and is suitable in particular for use in motor vehicles.

FIG. 2 shows by way of example an electrical load which is configured for connection to the open collector output 2 of the frequency divider circuit 16 in FIG. 1. For this purpose, the circuit comprises a signal input 17 which can be connected to the output 2 of the divider circuit 16 via an electrically conductive connection. The input 17 is connected to supply potential terminal 13 via a pull-up resistor 18. As a result, the electrical load can easily be connected to the open collector output 2. In order to condition signals, the electrical load also comprises a capacitor 19 which is connected between the input 17 and reference potential terminal 4, as well as a downstream RC element comprising a series resistor 20 and a capacitor 21 connected to ground. At the output end, a comparator 22 with switching hysteresis is connected at the output end to the RC element 20, 21 for further signal conditioning.

FIG. 3 depicts another embodiment of the frequency divider circuit shown in FIG. 1. This embodiment is constructed using MOS (Metal Oxide Semiconductor) circuit technology instead of being implemented in bipolar circuit technology. As the circuit in FIG. 3 largely corresponds to that in FIG. 1 in design and the advantageous method of operation, it will not be described once more at this point Instead of the npn-type output transistor 6 with upstream base resistor 5, a MOS transistor 23 is provided here as output transistor whose gate electrode is connected directly to the output Q of the flipflop 3 whose drain terminal is connected to the output 2 and whose source terminal is connected to the reference potential terminal 4 via the negative feedback resistor 8, and via the damping capacitor 9 in parallel therewith. In addition, instead of the npn-type transistor 10 and the voltage divider 11, 12, a further MOS transistor 24 is provided which operates as a comparator. The latter is connected by its source terminal to the source terminal of the transistor 23, by its drain terminal to the resetting input R of the flipflop 3 and via the resistor 14 to the supply potential terminal 13. The gate terminal of the further transistor 24 is directly connected to the reference potential terminal 4.

The open drain output which is provided in FIG. 3 corresponds in its function to the open collector output 2 in FIG. 1. The output transistor 23 is embodied as a n-type channel field-effect transistor of the depletion type. The comparator is embodied as an n-type channel transistor of the barrier layer type 24.

In the circuit of FIG. 3, the changeover of the reset signal which is made available at the drain terminal of the transistor 24 is determined by the impressed switch-off threshold voltage UGS of the field-effect transistor 24. This leads to depletion of charge carriers in the conductive channel and thus changes the transistor 24 into the switched-off state. As the voltage rises across the negative feedback resistor 8, the gate voltage is, considered in relative terms, negative, In conventional transistors this typically takes place at a voltage of approximately 0.7 volt.

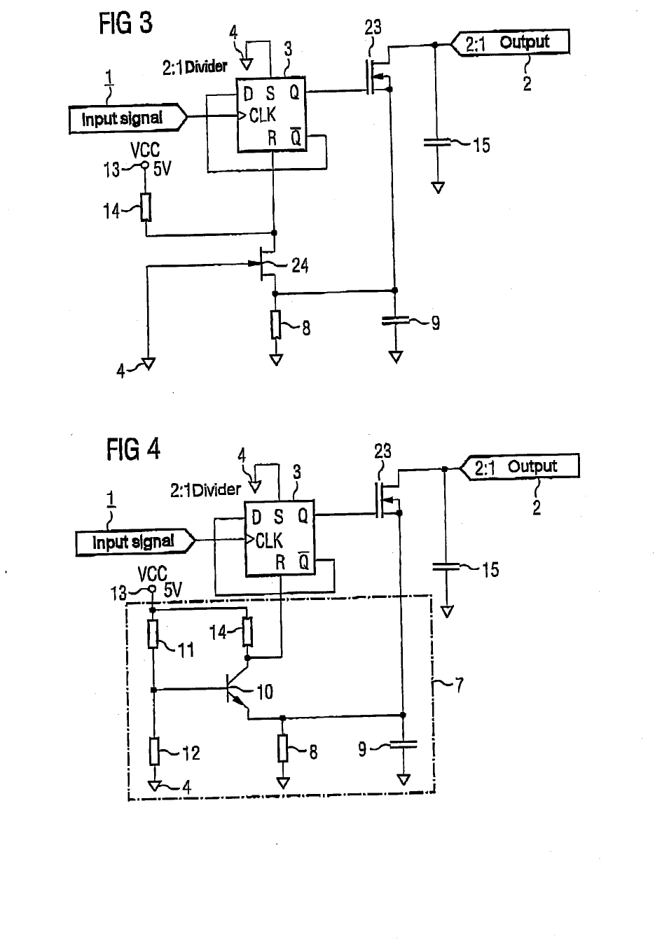

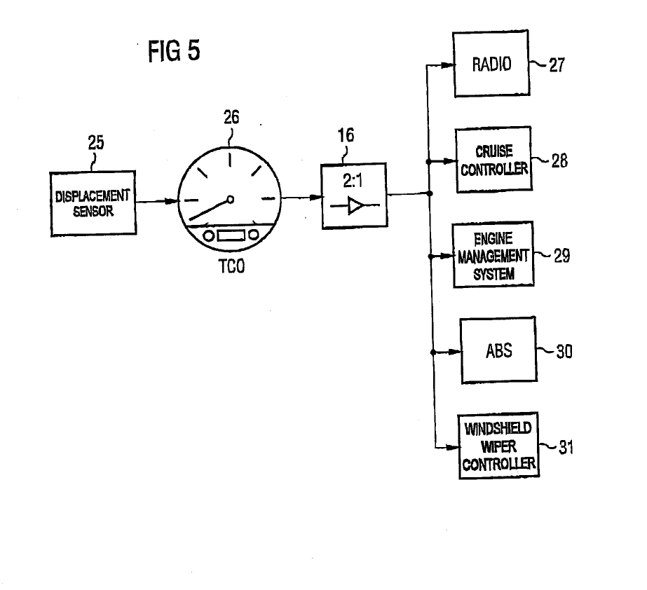

FIG. 4 depicts a third exemplary embodiment of a frequency divider circuit, based on the frequency divider circuit in FIG. 1. The present frequency divider circuit corresponds in design and method of operation largely to the frequency divider circuit in FIG. 1 and is therefore not described once more at this point. The cat registering mans 7 with the bipolar comparator transistor 10 corresponds in design and function to the current registering means 7 in FIG. 1. Only the output transistor 6 together with the base resistor 5 in FIG. 1 is, as in FIG. 3, replaced by a MOS output stage 23 here. This MOS circuit variant of the frequency divider thus corresponds to a combination of the exemplary embodiments in FIGS. 1 and 3.

The frequency divider circuits shown in FIGS. 1, 3 and 4 and the electrical load according to FIG. 2 have in common the fact that additional components which may be present and which are not of direct significance for the functioning of the short circuit protection, such as additional measures for protecting against interference and power supply units, are not shown.

Finally, FIG. 5 shows, by means of a simplified block circuit diagram, a possible application of the described frequency divider with short circuit protection in a vehicle. According to the figure, a displacement sensor 25, which makes available travel pulses, is provided as the signal source. The number of pulses per unit time provides information on the distance traveled. The displacement sensor can also be embodied as a tachograph. A tachograph 26, such as is generally used in motor vehicles for visually displaying the present speed of the vehicle, is connected to the output of the displacement sensor 25. The tachograph 26 can have further functions such as, for example, the average speed, distance traveled, total number of kilometers traveled, etc. A frequency divider 16, as given by way of example in FIGS. 1, 3 and 4, is connected to the output of the displacement sensor 25 or to the output of the tachograph 26, the frequency divider 16 carrying out frequency division by two as well as signal conditioning and providing protection against short circuits. The frequency divider 16 actuates further components which require a lower input frequency than that made available by the displacement sensor 25, these being for example radios 27, cruise controllers 28, engine management system of the motor vehicle 29, controller of the windshield wipers 31 and traction control systems, in particular antilock brake systems 30, antislip controllers, electronic stability aids or the like.

The invention being thus described, it will be obvious that the same may be varied in many ways. The variations are not to be regarded as a departure from the spirit and scope of the invention, and all such modifications as would be obvious to one skilled in the art are intended to be included within the scope of the following claims.

I claim:

1. A frequency dividing circuit arrangement, comprising
a multivibrator configured as a frequency divider and including a clock input for feeding in an input signal; an output at which a signal with a divided frequency of the input signal is made available; and with a resetting input, and
a current registering means comprising a comparator including a first input which is coupled to the output of the multivibrator in order to register an output current which is dependent on tae signal with the divided frequency, a second input which is coupled to a reference source; and an output which is coupled to the resetting input of the multivibrator and actuates the resetting input as a function of a comparison result.

2. The circuit arrangement according to claim 1, further comprising an output transistor including a control input which is connected to the output of the multivibrator, and a controlled path having a terminal which is connected to the first input of the comparator for feeding in the output current.

3. The circuit arrangement according to claim 2, wherein the current registering means comprises a negative feedback resistor which is connected between the terminal of the controlled path of the output transistor and a reference potential terminal in or to make available a voltage which is assigned to the output current.

4. The circuit arrangement according to claim 2, wherein the current registering means comprises a damping capacitor which is connected between the terminal of the controlled path of the output transistor and a reference potential terminal and is configured to reliably detect a short circuit between a second terminal of the controlled path of the output transistor and a supply potential terminal.

5. The circuit arrangement according to claim 4, further comprising a suppression capacitor connected between the second terminal of the controlled path of the output transistor and a reference potential terminal and configured to suppress radio frequency interference.

6. The circuit arrangement according to claim 3, wherein the current registering means comprises a damping capacitor which is connected between the terminal of the controlled path of the output transistor and a reference potential terminal and is configured to reliably detect a short circuit between a second terminal of the controlled path of the output transistor and a supply potential terminal.

7. The circuit arrangement according to claim 6, farther comprising a suppression capacitor connected between the second terminal of the controlled path of the output transistor and a reference potential terminal and configured to suppress radio frequency interference.

8. The circuit arrangement according to claim 1, wherein the reference source comprises a voltage divider with an output node which is connected to the second input of the comparator.

9. The circuit arrangement according to claim 2, wherein the reference source comprises a voltage divider with an output node which is connected to the second input of the comparator.

10. The circuit arrangement according to claim 3, wherein the reference source comprises a voltage divider with an output node which is connected to the second input of the comparator.

11. The circuit arrangement according to claim 1 (to 6), wherein the multivibrator is a flipflop.

12. The circuit arrangement according to claim 3 (to 6), wherein the multivibrator is a flipflop.

13. The circuit arrangement according to claim 10, wherein the multivibrator is a flipflop.

14. The circuit arrangement according to claim 1, wherein the frequency divider makes available a signal with a divided frequency of the input signal which corresponds to half the frequency of the input signal.

15. The circuit arrangement according to claim 3, wherein the frequency divider makes available a signal with a divided frequency of the input signal which corresponds to half the frequency of the input signal.

16. The circuit arrangement according to claim 8, wherein the frequency divider makes available a signal with a divided frequency of the input signal which corresponds to half the frequency of the input signal.

17. The cat arrangement according to claim 11, wherein the frequency divider makes available a signal with a divided frequency of the input signal which corresponds to half the frequency of the input signal.

18. The circuit according to claims 1, characterized in that the clock input of the multivibrator is connected to a pulse source which outputs travel-dependent pulses.

19. The circuit according to claims 8, characterized in that the clock input of the multivibrator is connected to a pulse source which outputs travel-dependent pulses.

20. The circuit according to claims 11, characterized in that the clock input of the multivibrator is connected to a pulse source which outputs travel-dependent pulses.
